(19) United States
(12) Patent Application Publication
(10) Pub. No.: US 2007/0045764 A1
(43) Pub. Date: Mar. 1, 2007

(54) Semiconductor device

(76) Inventors: Tetsuo Hatakeyama, Yokohama-shi (JP); Takashi Shinohe, Yokosuka-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/505,809

(22) Filed: Aug. 18, 2006

(30) Foreign Application Priority Data
Aug. 25, 2005 (JP) 2005-244378

(51) Int. Cl. H01L 31/07

(52) U.S. Cl. 257/471

(57) ABSTRACT

A semiconductor device includes a semiconductor substrate of a first conductivity type, a semiconductor region of the first conductivity type formed on a top surface of the semiconductor substrate, a lower electrode formed on a bottom surface of the semiconductor substrate, an upper electrode formed on a top surface of the semiconductor region, a buried semiconductor layer of a second conductivity type formed in the semiconductor region, a first semiconductor layer of the second conductivity type, formed on the top surface of the semiconductor region and connected to the upper electrode, and a second semiconductor layer of the second conductivity type, formed on a side surface of the semiconductor region and connected to the buried semiconductor layer and the first semiconductor layer, the second semiconductor layer having a lower second conductivity type impurity concentration than the buried semiconductor layer.

### CROSS-REFERENCE TO RELATED APPLICATIONS

This application is based upon and claims the benefit of priority from prior Japanese Patent Application No. 2005-244378, filed Aug. 25, 2005, the entire contents of which are incorporated herein by reference.

### BACKGROUND OF THE INVENTION

1. Field of the Invention

The present invention relates to a semiconductor device.

2. Description of the Related Art

Power semiconductor devices such as Schottky barrier diodes have been requested to have their on resistances reduced and their breakdown voltages increased. In response to such a request, efforts have been made to achieve both reduced on resistance and increased breakdown voltage by providing a drift layer and adjusting the concentration and thickness of the drift layer.

In recent years, to further reduce the on resistance and to further increase the breakdown voltage, a structure has been proposed in which a floating semiconductor layer (buried semiconductor layer) is provided in the drift layer (see JP-A 9-191109 (KOKAI)).

However, the above conventional structure requires electric charges (for example, holes) to be supplied to the buried semiconductor layer upon turn-on in order to neutralize electric charges (for example, electrons) accumulated in the buried semiconductor layer. Thus, upon turn-on, a forward voltage must be raised substantially to the built-in voltage of a pn junction to supply electric charges (for example, holes) to the buried semiconductor layer. This disadvantageously increases a switching loss.

Thus, a problem with the conventional power semiconductor device is that the switching characteristic is degraded upon turn-on.

### BRIEF SUMMARY OF THE INVENTION

According to a first aspect of the present invention, there is provide a semiconductor device comprising: a semiconductor substrate of a first conductivity type; a semiconductor region of the first conductivity type formed on a top surface of the semiconductor substrate; a lower electrode formed on a bottom surface of the semiconductor substrate; an upper electrode formed on a top surface of the semiconductor region; a buried semiconductor layer of a second conductivity type formed in the semiconductor region; a first semiconductor layer of the second conductivity type, formed on the top surface of the semiconductor region and connected to the upper electrode; and a second semiconductor layer of the second conductivity type, formed on a side surface of the semiconductor region and connected to the buried semiconductor layer and the first semiconductor layer, the second semiconductor layer having a lower second conductivity type impurity concentration than the buried semiconductor layer.

According to a second aspect of the present invention, there is provide a semiconductor device comprising: a semiconductor substrate of a first conductivity type; a semiconductor region of the first conductivity type formed on a top surface of the semiconductor substrate and having a hole; a lower electrode formed on a bottom surface of the semiconductor substrate; an upper electrode formed on a top surface of the semiconductor region; a buried semiconductor layer of a second conductivity type formed in the semiconductor region; and a second conductivity type semiconductor layer formed on a side surface of the hole of the semiconductor region, the second conductivity type semiconductor layer being connected to the buried semiconductor layer and the upper electrode, and the second conductivity type semiconductor layer having a lower second conductivity type impurity concentration than the buried semiconductor layer.

According to a third aspect of the present invention, there is provide a semiconductor device comprising: a semiconductor substrate of a first conductivity type; a semiconductor region of the first conductivity type formed on a top surface of the semiconductor substrate; a lower electrode formed on a bottom surface of the semiconductor substrate; an upper electrode formed on a top surface of the semiconductor region; a buried semiconductor layer of a second conductivity type formed in the semiconductor region; a first semiconductor layer of the second conductivity type, formed on the top surface of the semiconductor region and connected to the upper electrode; and a stacked structure formed on a side surface of the semiconductor region and comprising a first conductivity type semiconductor layer and a second semiconductor layer of the second conductivity type, the second semiconductor layer being connected to the buried semiconductor layer and the first semiconductor layer.

According to a fourth aspect of the present invention, there is provide a semiconductor device comprising: a semiconductor substrate of a first conductivity type; a semiconductor region of the first conductivity type formed on a top surface of the semiconductor substrate and having a hole; a lower electrode formed on a bottom surface of the semiconductor substrate; an upper electrode formed on a top surface of the semiconductor region; a buried semiconductor layer of a second conductivity type formed in the semiconductor region; and a stacked structure formed on a side surface of the hole of the semiconductor region, the stacked structure comprising a first conductivity type semiconductor layer and a second conductivity type semiconductor layer connected to the buried semiconductor layer and the upper electrode.

### BRIEF DESCRIPTION OF THE SEVERAL VIEWS OF THE DRAWING

FIG. 1 is a sectional view showing the configuration of a power semiconductor device (Schottky barrier diode) in accordance with a first embodiment;

FIG. 2 is a top view showing the power semiconductor device in accordance with the first embodiment;

FIG. 3 is a plan view showing the positional relationship among patterns for the power semiconductor device in accordance with the first embodiment;

FIG. 4 is a graph showing an example of the turn-on characteristic of the Schottky barrier diode in accordance with the first embodiment;

FIG. 5 is a graph showing an example of the turn-on characteristic of a Schottky barrier diode in accordance with a comparative example of the first embodiment;

FIG. 6 is a graph showing an example of the relationship between the impurity concentration of a p-type semiconductor layer and the breakdown voltage;

FIG. 7 is a sectional view showing the configuration of a power semiconductor device (Schottky barrier diode) in accordance with a second embodiment;

FIG. 8 is a plan view showing the positional relationship among patterns for the power semiconductor device in accordance with the second embodiment;

FIG. 9 is a sectional view showing the configuration of a power semiconductor device (Schottky barrier diode) in accordance with a third embodiment;

FIG. 10 is a plan view showing the positional relationship among patterns for the power semiconductor device in accordance with the third embodiment;

FIG. 11 is a sectional view showing the configuration of a variation of the power semiconductor device in accordance with the third embodiment;

FIG. 12 is a sectional view showing the configuration of a power semiconductor device (Schottky barrier diode) in accordance with a fourth embodiment;

FIG. 13 is a plan view showing the positional relationship among patterns for the power semiconductor device in accordance with the fourth embodiment;

FIG. 14 is a sectional view showing the configuration of a variation of the power semiconductor device in accordance with the fourth embodiment; and

FIG. 15 is a sectional view showing the configuration of a power semiconductor device (Schottky barrier diode) in accordance with a fifth embodiment.

### DETAILED DESCRIPTION OF THE INVENTION

Embodiments of the present invention will be described with reference to the drawings.

(Embodiment 1)

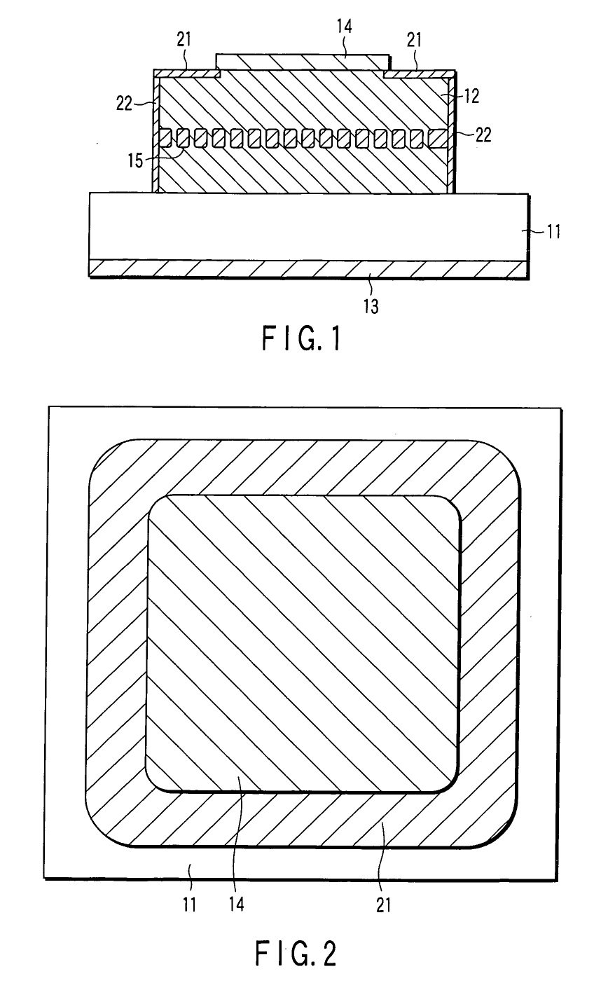

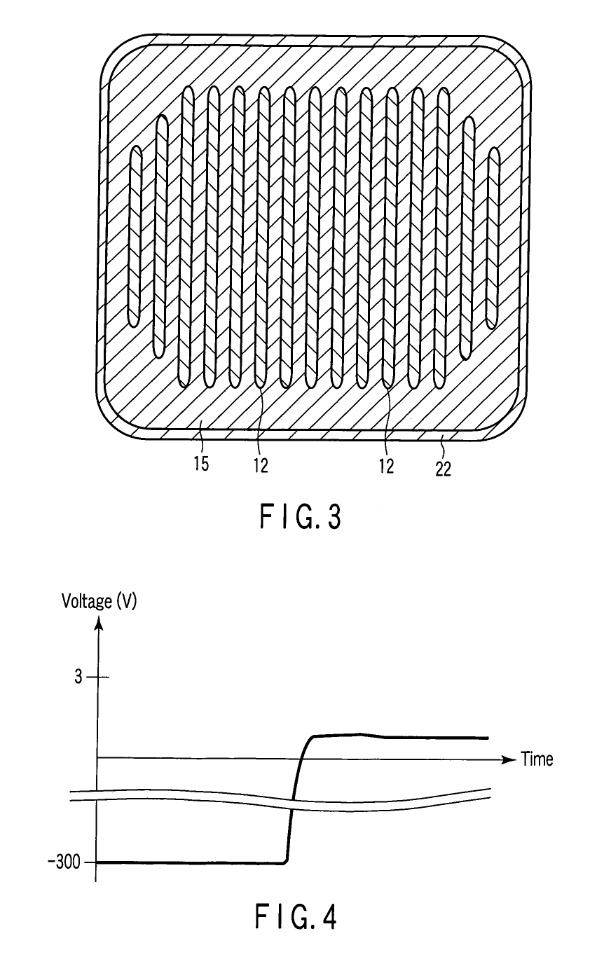

With reference to FIGS. 1 to 3, description will be given of a power semiconductor device (Schottky barrier diode) in accordance with a first embodiment. FIG. 1 is a sectional view. FIG. 2 is a top view. FIG. 3 is a plan view showing the positional relationship among patterns.

For example, silicon carbide (SiC) is used for an n-type semiconductor substrate (n⁺-type semiconductor substrate) 11. An n-type semiconductor region (n⁻-type semiconductor region) 12 is formed on a top surface (principal surface) of the n-type semiconductor substrate 11. The n-type semiconductor region 12 functions as a drift layer of the Schottky barrier diode. A cathode electrode (lower electrode) 13 is formed on a bottom surface (back surface) of the n-type semiconductor substrate 11. Further, an anode electrode (upper electrode) 14 is formed on a top surface of the n-type semiconductor region 12.

A p-type buried semiconductor layer (p⁻-type buried semiconductor layer) 15 is formed in the n-type semiconductor region 12. As shown in FIG. 1, the p-type buried semiconductor layer 15 is formed between a lower layer portion and an upper layer portion of the n-type semiconductor region 12. Further, as shown in FIG. 3, an intermediate layer portion (portion between the upper and lower layer portions) of the n-type semiconductor region 12 is partitioned into a plurality of parts by the p-type buried semiconductor layer 15. The p-type buried semiconductor layer 15 floats electrically when the Schottky barrier diode is reversely biased, as described later. Furthermore, in the reverse bias state, electrons are accumulated in the p-type buried semiconductor layer 15.

A p-type semiconductor layer 21 connected to the anode 14 is formed on a top surface of the n-type semiconductor region 12. As shown in FIG. 2, the p-type semiconductor layer 21 is formed to surround the anode 14. The concentration (per unit volume) of p-type impurities in the p-type semiconductor layer 21 is higher than that in the p-type buried semiconductor layer 15. The p-type semiconductor layer 21 is formed by implanting ions of p-type impurities in a top surface region of the n-type semiconductor region 12.

A p-type semiconductor layer (p⁻-type semiconductor layer) 22 is formed on side surfaces of the n-type semiconductor region 12; the p-type semiconductor layer 22 is connected to the p-type buried semiconductor layer 15 and p-type semiconductor layer 21. As seen in FIGS. 1 and 3, the p-type semiconductor layer 22 is formed to surround the n-type semiconductor region 12. The concentration (per unit volume) of p-type impurities in the p-type semiconductor layer 22 is lower than that in the p-type buried semiconductor layer 15. The p-type semiconductor layer 22 is formed by implanting ions of p-type impurities in side surface regions of the n-type semiconductor region 12. Specifically, with the substrate rotated, oblique ion implantation is used to implant p-type impurity ions in the side surface regions of the n-type semiconductor region 12 (the rotation axis is perpendicular to the principal surface of the n-type semiconductor substrate 11).

As is understood from the above description, the anode 14 and the p-type buried semiconductor layer 15 are connected together via the p-type semiconductor layer 21 and p-type semiconductor layer 22. The p-type semiconductor layer 22 is not provided in the conventional configuration. In the present embodiment, the p-type semiconductor layer 22 is provided on the side surfaces of the n-type semiconductor region 12. Consequently, the switching characteristic obtained upon turn-on can be improved as described below.

While a reverse bias is being applied to the Schottky barrier diode, electrons are accumulated in the p-type buried semiconductor layer 15. Thus, to turn on the Schottky barrier diode (to change the Schottky barrier diode from the reverse bias state to a forward bias state), it is necessary to supply holes to the buried semiconductor layer 15 in order to neutralize the electric charges (electrons) accumulated in the buried semiconductor layer 15. However, in the conventional device, only the p-type semiconductor layer 21 is provided on the top surface of the n-type semiconductor region 12. Consequently, holes are supplied to the buried semiconductor layer 15 via the pn junction between the p-type semiconductor layer 21 and the n-type semiconductor region 12. Thus, the forward voltage rises substantially to the built-in voltage (for SiC, about 3 V) of the pn junction. This increases a switching loss upon turn-on.

In the present embodiment, the p-type semiconductor layer 22 is provided on the side surfaces of the n-type semiconductor region 12. Consequently, the anode 14 can supply holes to the p-type buried semiconductor layer 15 via the p-type semiconductor layer 21 and p-type semiconductor layer 22. This makes it possible to suppress a rise in voltage upon turn-on to reduce the switching loss.

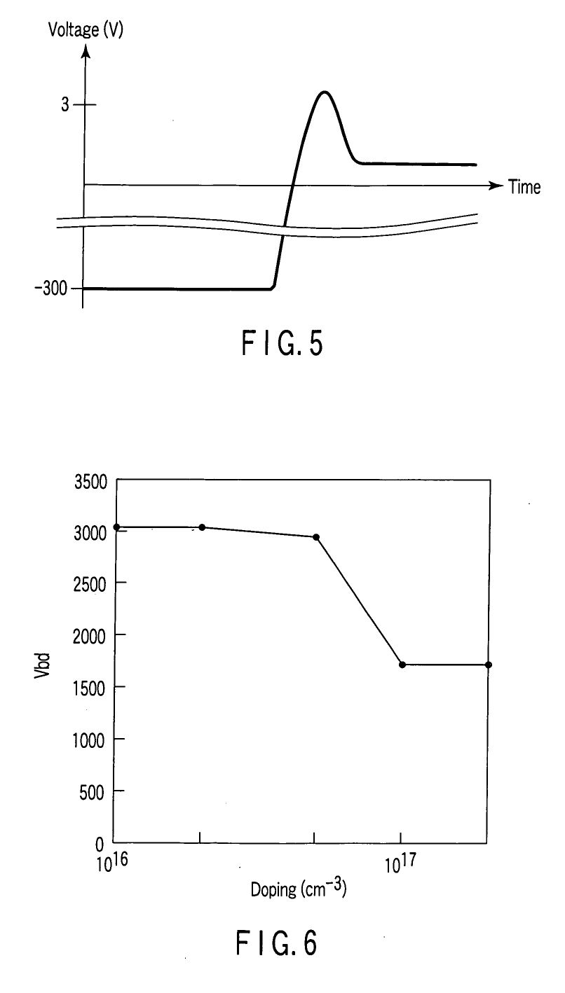

FIG. 4 is a graph showing an example of the turn-on characteristic of the Schottky barrier diode in accordance with the present embodiment. FIG. 5 is a graph showing an example of the turn-on characteristic of a conventional Schottky barrier diode. In the conventional device, a voltage peak occurs at about 3 V. However, in the present embodiment, such a phenomenon does not occur.

Thus, in the present embodiment, the p-type semiconductor layer 22 is provided to enable the switching characteristic obtained upon turn-on to be improved. This makes it possible to reduce the switching loss upon turn-on. However, if the p-type semiconductor layer 22 is not entirely depleted when a reverse bias voltage (for example, at least several hundred volts) is applied to the Schottky barrier diode, the resistance between the anode 14 and the n-type semiconductor substrate 11 is not increased. This reduces the breakdown voltage provided upon the application of the reverse bias.

FIG. 6 is a graph showing an example of the relationship between the impurity concentration (doping concentration) of the p-type semiconductor layer 22 and breakdown voltage Vbd. The impurity concentration of the n-type semiconductor region 12 is 1×10¹⁶ cm⁻³. An increase in the impurity concentration of the p-type semiconductor layer 22 reduces the width (thickness) of a depletion layer of the p-type semiconductor layer 22. This prevents the p-type semiconductor layer 22 from being completely depleted, thus lowering the breakdown voltage.

To prevent the above problem, it is important to set the thickness and impurity concentration of the p-type semiconductor layer 22 so as to completely deplete the p-type semiconductor layer 22 in the reverse bias state. In the present embodiment, the p-type semiconductor layer 22 has a lower impurity concentration (per unit volume) than the p-type buried semiconductor layer 15. The low impurity concentration of the p-type semiconductor layer 22 enables an increase in the width of the depletion layer of the p-type semiconductor layer 22. As a result, in the reverse bias state, the p-type semiconductor layer 22 can be depleted easily and completely. This makes it possible to prevent the breakdown voltage from lowering upon the application of the reverse bias.

Therefore, in the present embodiment, it is possible to improve the switching characteristic obtained upon turn-on and to prevent the breakdown voltage from lowering upon the application of the reverse bias. A power semiconductor device can thus be obtained which has excellent characteristic and a high reliability.

Desirable values for the impurity concentration and thickness of the p-type semiconductor layer 22 are, for example, as described below.

To obtain a favorable turn-on characteristic, it is important that a current path be present between the anode 14 and the p-type buried semiconductor layer 15. In a zero bias state (in which the voltage between the cathode 13 and the anode 14 is zero), the completely depleted p-type semiconductor layer 22 prevents the formation of a current path between the anode 14 and the p-type buried semiconductor layer 15. This precludes a favorable turn-on characteristic from being obtained.

The expression shown below represents a condition for preventing the p-type semiconductor layer 22 from being completely depleted in a zero bias state.
Na×L>(2×Nd×ε×Eg/e)^{1/2}
In this expression:
Na: impurity concentration of the p-type semiconductor layer 22 per unit volume,
L: thickness of the p-type semiconductor layer 22,
Nd: impurity concentration of the n-type semiconductor region 12 per unit volume, ε: dielectric constant of a semiconductor material used,
Eg: bandgap of the semiconductor material used, and
e: elementary electric charge.

For example, when Nd=1×10¹⁶ cm⁻³, Na×L>5.7×10¹¹ cm⁻². That is, 5.7×10¹¹ cm⁻² is the lower limit of Na×L. However, too large a value for Na×L precludes the p-type semiconductor layer 22 from being completely depleted in the reverse bias state (for example, at least several hundred volts). This lowers the breakdown voltage. For example, a value about 10 times as large as the lower limit of Na×L(5.7×10¹² cm⁻²) is the upper limit of Na×L. Accordingly, the following condition is desirable.
5.7×10¹² cm⁻²>Na×L>5.7×10¹¹ cm⁻²
(Embodiment 2)

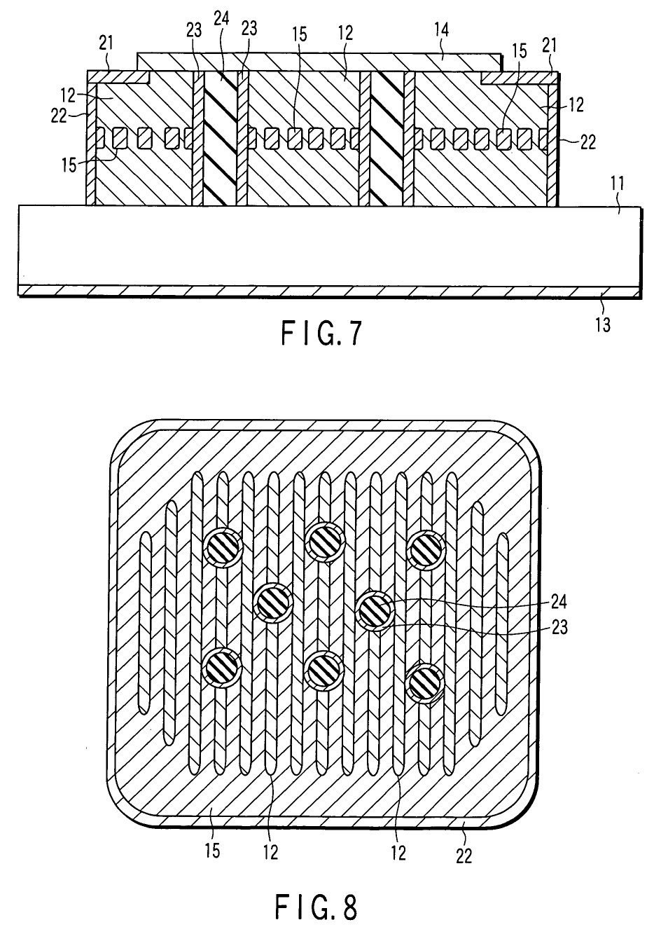

With reference to FIGS. 7 and 8, description will be given of a power semiconductor device (Schottky barrier diode) in accordance with a second embodiment of the present invention. FIG. 7 is a sectional view. FIG. 8 is a plan view showing the positional relationship among patterns. The basic configuration of the second embodiment is similar to that of the first embodiment. Accordingly, the matters described in the first embodiment will not be described in detail.

In the present embodiment, p-type semiconductor layers (p⁻-type semiconductor layers) 23 are formed on the side surfaces of respective holes penetrating the n-type semiconductor region 12. The p-type semiconductor layers 23 connect the anode 14 to the p-type buried semiconductor layer 15. The concentration (per unit volume) of p-type impurities in the p-type semiconductor layers 23 is lower than that in the p-type buried semiconductor layer 15. A method for forming p-type semiconductor layers 23 is similar to that for forming a p-type semiconductor layer 22 as described in the first embodiment. That is, with the substrate rotated, oblique ion implantation is used to implant ions of p-type impurities in the side surface regions of the holes formed in the n-type semiconductor region 12. The hole surrounded by the p-type semiconductor layer 23 is filled with an insulator (for example, silicon oxide) 24.

As described above, in the present embodiment, the anode 14 and the p-type buried semiconductor layer 15 are connected together by the p-type semiconductor layers 23. Consequently, upon turn-on, the anode 14 can supply holes to the p-type buried semiconductor later 15 via the p-type semiconductor layers 23. As in the case of the first embodiment, this makes it possible to suppress a rise in the voltage upon turn-on to reduce the switching loss.

In the present embodiment, to obtain a sufficient breakdown voltage upon the application of the reverse bias, it is important to set the thickness and impurity concentration of the p-type semiconductor layers 23 so as to completely deplete the p-type semiconductor layer 23 in the reverse bias state, as in the case of the first embodiment. In the present embodiment, the concentration (per unit volume) of impurities in the p-type semiconductor layers 23 is lower than that in the p-type buried semiconductor layer 15. The low impurity concentration of the p-type semiconductor layer 23 serves to increase the width of the depletion layer of the p-type semiconductor layer 23. As a result, in the reverse bias state, the p-type semiconductor layers 23 can be depleted easily and completely. This makes it possible to prevent the breakdown voltage from lowering upon the application of the reverse bias.

Therefore, in the present embodiment, it is possible to improve the switching characteristic obtained upon turn-on and to prevent the breakdown voltage from lowering upon the application of the reverse bias, as in the case of the first embodiment. A power semiconductor device can thus be obtained which has excellent characteristic and a high reliability.

Further, in the present embodiment, the p-type semiconductor layers 23 are formed on the side surfaces of the holes formed in the n-type semiconductor region 12. This enables an increase in the number of paths between the anode 14 and the p-type buried semiconductor layer 15. It is thus possible to efficiently supply holes to the p-type buried semiconductor layer 15 upon turn-on.

In the present embodiment, the p-type semiconductor layer 22 is provided as in the case of the first embodiment. However, the p-type semiconductor layer 22 need not necessarily be provided.

(Embodiment 3)

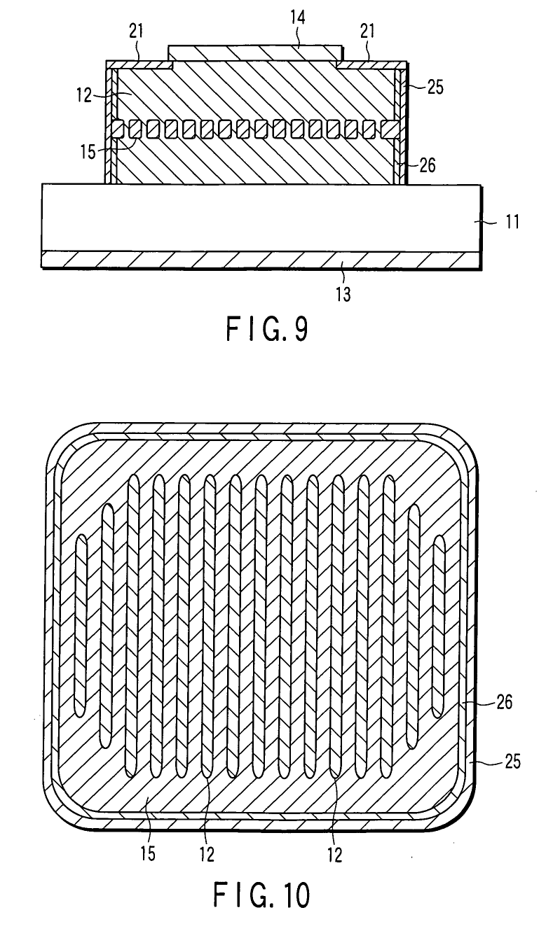

With reference to FIGS. 9 and 10, description will be given of a power semiconductor device (Schottky barrier diode) in accordance with a third embodiment. FIG. 9 is a sectional view. FIG. 10 is a plan view showing the positional relationship among patterns. The basic configuration of the third embodiment is similar to that of the first embodiment. Accordingly, the matters described in the first embodiment will not be described in detail.

In the present embodiment, a stacked structure is provided on the side surfaces of the n-type semiconductor region 12; the stacked structure is formed of a p-type semiconductor layer (p⁻-type semiconductor layer) 25 and an n-type semiconductor layer (n⁻-type semiconductor layer) 26. Similarly to the p-type semiconductor layer 22 in accordance with the first embodiment, the p-type semiconductor layer 25 is connected to the p-type buried semiconductor layer 15 and p-type semiconductor layer 21. The concentration (per unit volume) of p-type impurities in the p-type semiconductor layers 25 is lower than that in the p-type buried semiconductor layer 15. Further, the concentration (per unit volume) of n-type impurities in the n-type semiconductor layers 26 is higher than that in the n-type semiconductor region 12.

A method for forming a p-type semiconductor layer 25 is similar to that for forming a p-type semiconductor layer 22 as described in the first embodiment. That is, with the substrate rotated, oblique ion implantation is used to implant ions of p-type impurities in the side surface region of the n-type semiconductor region 12. A method for forming an n-type semiconductor layer 26 is also similar to that for forming a p-type semiconductor layer 25. With the substrate rotated, oblique ion implantation is used to implant ions of n-type impurities in the side surface region of the n-type semiconductor region 12. Further, ion implantation energy is adjusted to increase the implantation depth of n-type impurities above that of p-type impurities. Consequently, the n-type semiconductor layer 26 is formed inside the p-type semiconductor layer 25.

As described above, in the present embodiment, the anode 14 and the p-type buried semiconductor layer 15 are connected together by the p-type semiconductor layer 25. Consequently, upon turn-on, the anode 14 can supply holes to the p-type buried semiconductor later 15 via the p-type semiconductor layer 25. As in the case of the first embodiment, this makes it possible to suppress a rise in the voltage upon turn-on to reduce the switching loss.

Further, in the present embodiment, the n-type semiconductor layer 26 is provided which has a higher n-type impurity concentration than the n-type semiconductor region 12. This makes it possible to increase the concentration of p-type impurities in the p-type semiconductor layer 25 and to increase the width of the depletion layer of the p-type semiconductor layer 25. That is, in the pn junction, the positive and negative electric charges in the depletion layer are balanced. Accordingly, when the concentration of p-type impurities in the p-type semiconductor layer 25 is increased without forming an n-type semiconductor layer 26, the width of the depletion layer of the p-type semiconductor layer 25 necessarily decreases. In the present embodiment, the n-type semiconductor layer 26 with a high n-type impurity concentration is provided. This enables an increase in the width of the depletion layer in the p-type semiconductor layer 25 even with an increase in the p-type impurity concentration of the p-type semiconductor layer 25. Therefore, in the present embodiment, the p-type semiconductor layer 25 can be depleted easily and completely in the reverse bias state as in the case of the first embodiment. This makes it possible to prevent the breakdown voltage from lowering upon the application of the reverse bias.

The p-type impurity concentration of the p-type semiconductor layer 25 is preferably equivalent to the n-type impurity concentration of the n-type semiconductor layer 26. Specifically, each of the p- and n-type impurity concentrations is desirably at most 1×10¹⁴ cm⁻² and higher than 5.7×10¹² cm⁻².

As described above, in the present embodiment, it is also possible to improve the switching characteristic obtained upon turn-on and to prevent the breakdown voltage from lowering upon the application of the reverse bias. A power semiconductor device can thus be obtained which has excellent characteristic and a high reliability.

Further, the present embodiment can increase the p-type impurity concentration of the p-type semiconductor layer 25 to reduce the resistance of the p-type semiconductor layer 25, as described above. It is thus possible to reduce the resistance of the current path between the anode 14 and the p-type buried semiconductor layer 15. This also serves to improve the switching characteristic obtained upon turn-on.

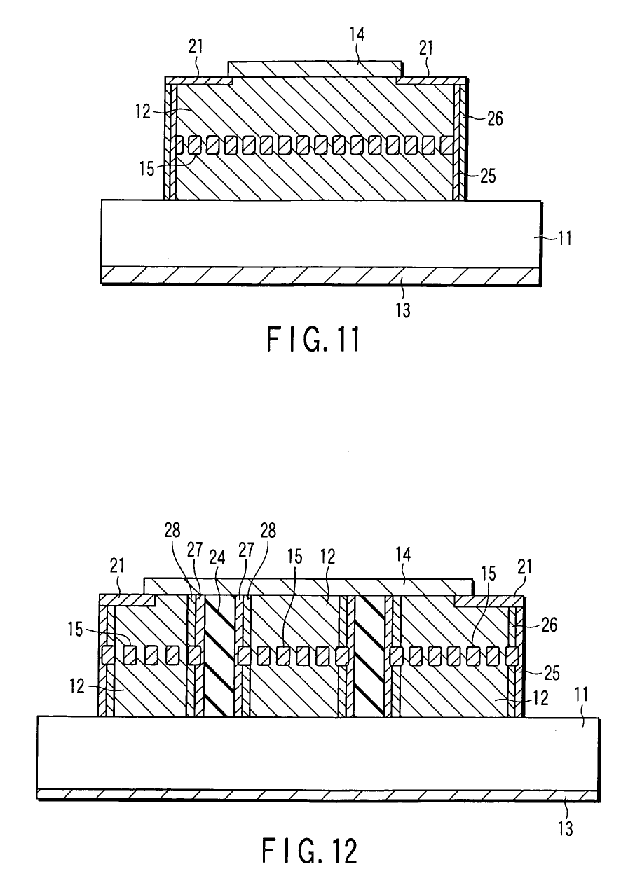

FIG. 11 is a diagram showing a variation of the present embodiment. In the variation, a stacked structure is also provided on the side surfaces of the n-type semiconductor region 12; the stacked structure is formed of the p-type semiconductor layer (p⁻-type semiconductor layer) 25 and the n-type semiconductor layer (n⁻-type semiconductor layer) 26. However, in the above embodiment, the n-type semiconductor layer 26 is provided between the p-type semiconductor layer 25 and the n-type semiconductor region 12, whereas in the present variation, the p-type semiconductor layer 25 is provided between the n-type semiconductor layer 26 and the n-type semiconductor region 12. Thus, effects similar to those of the above embodiments can be exerted even when the order is reversed in which the p-type semiconductor layer 25 and the n-type semiconductor layer 26 are stacked.

(Embodiment 4)

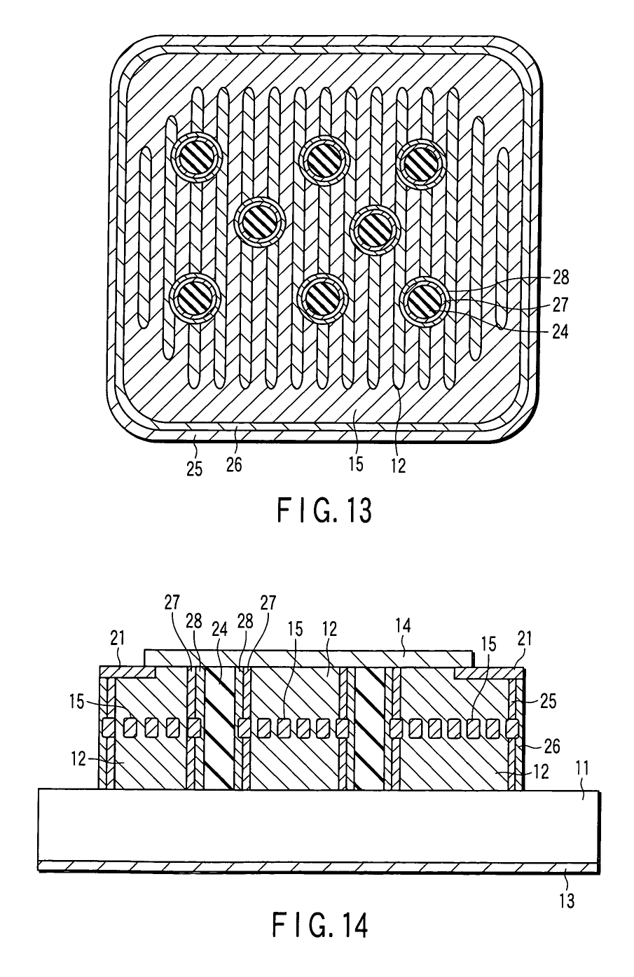

With reference to FIGS. 12 and 13, description will be given of a power semiconductor device (Schottky barrier diode) in accordance with a fourth embodiment. FIG. 12 is a sectional view. FIG. 13 is a plan view showing the positional relationship among patterns. As seen in FIGS. 12 and 13, a Schottky barrier diode in accordance with the present embodiment has a configuration in which the configurations of the Schottky barrier diodes in accordance with the first to third embodiments are combined together. Accordingly, the matters described in the first to third embodiments will not be described in detail.

In the present embodiment, stacked structures are provided on side surfaces of holes penetrating the n-type semiconductor region 12; each of the stacked structures is formed of a p-type semiconductor layer (p⁻-type semiconductor layer) 27 and an n-type semiconductor layer (n⁻-type semiconductor layer) 28. The p-type semiconductor layer 27 is connected to the anode 14 and p-type buried semiconductor layer 15. The p-type impurity concentration (per unit volume) of the p-type semiconductor layers 27 is lower than that of the p-type buried semiconductor layer 15. Further, the n-type impurity concentration (per unit volume) of the n-type semiconductor layers 28 is higher than that of the n-type semiconductor region 12. The hole surrounded by the p-type semiconductor layer 27 is filled with an insulator (for example, silicon oxide) 24.

As described above, in the present embodiment, the anode 14 and the p-type buried semiconductor layer 15 are connected together by the p-type semiconductor layer 27. Consequently, upon turn-on, the anode 14 can supply holes to the p-type buried semiconductor later 15 via the p-type semiconductor layer 27. As in the case of the already described embodiments, this makes it possible to suppress a rise in the voltage upon turn-on to reduce the switching loss.

Further, in the present embodiment, the n-type semiconductor layer 28 is provided which has a higher n-type impurity concentration than the n-type semiconductor region 12. This enables an increase in the width of the depletion layer in the p-type semiconductor layer 27 even with an increase in the p-type impurity concentration of the p-type semiconductor layer 27 as described in the third embodiment. Therefore, in the present embodiment, the p-type semiconductor layer 25 can also be depleted easily and completely in the reverse bias state. This makes it possible to prevent the breakdown voltage from lowering upon the application of the reverse bias. Furthermore, as described in the third embodiment, it is possible to reduce the resistance of the p-type semiconductor layer 27 and thus the resistance of the current path between the anode 14 and the p-type buried semiconductor layer 15.

As described above, in the present embodiment, it is also possible to improve the switching characteristic obtained upon turn-on and to prevent the breakdown voltage from lowering upon the application of the reverse bias. A power semiconductor device can thus be obtained which has excellent characteristic and a high reliability.

FIG. 14 is a diagram showing a variation of the present embodiment. In the variation, stacked structures are also provided on the side surfaces of the holes penetrating the n-type semiconductor region 12; each of the stacked structures is formed of the p-type semiconductor layer (p⁻-type semiconductor layer) 27 and the n-type semiconductor layer (n⁻-type semiconductor layer) 28. However, in the above embodiment, the n-type semiconductor layer 28 is provided between the p-type semiconductor layer 27 and the n-type semiconductor region 12, whereas in the present variation, the p-type semiconductor layer 27 is provided between the n-type semiconductor layer 28 and the n-type semiconductor region 12. Thus, effects similar to those of the above embodiments can be exerted even when the order is reversed in which the p-type semiconductor layer 27 and the n-type semiconductor layer 28 are stacked.

In the present embodiment, the p-type semiconductor layer 25 and the n-type semiconductor layer 26 are provided as in the case of the third embodiment. However, the p-type semiconductor layer 25 and the n-type semiconductor layer 26 need not necessarily be provided.

(Embodiment 5)

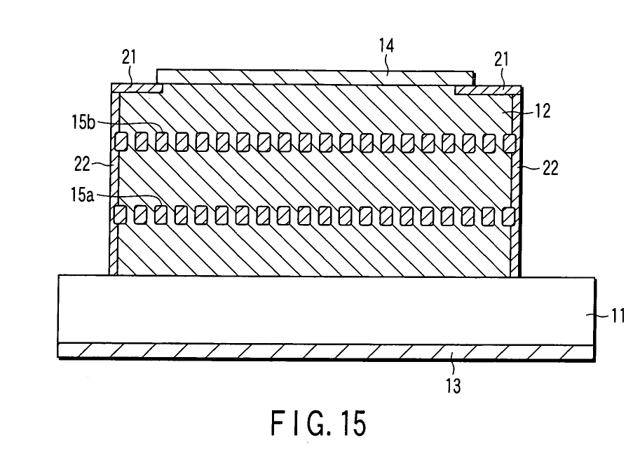

With reference to FIG. 15, description will be given of a power semiconductor device (Schottky barrier diode) in accordance with a fifth embodiment. The basic configuration of the fifth embodiment is similar to that of the first embodiment. Accordingly, the matters described in the first embodiment will not be described in detail.

In the first embodiment, the single p-type buried semiconductor layer 15 is provided. However, in the present embodiment, a plurality of (in the present example, two) p-type buried semiconductor layers, that is, p-type buried semiconductor layers 15a and 15b, are provided. Even with the plurality of p-type buried semiconductor layers, the fifth embodiment has a basic configuration similar to that of the first embodiment and produces effects similar to those of the first embodiment.

The configuration provided with the plurality of p-type buried semiconductor layers is also applicable to Schottky barrier diodes such as those shown in the second to fourth embodiments.

In the above first to fifth embodiments, configurations such as those shown in the first to fifth embodiments can be adopted even if all the n-type components are changed to the p type, while all the p-type components are changed to the n type. In this case, it is possible to exert effects similar to those described in the first to fifth embodiments.

In the description of the first to fifth embodiments, the Schottky barrier diodes are examples of a power semiconductor device. However, configurations such as those shown in the first to fifth embodiments are applicable to power semiconductor devices such as a power MOSFET and a junction FET.

In the above first to fifth embodiments, the area of the n-type semiconductor substrate 11 is larger than the n-type semiconductor region 12. However, the area of the n-type semiconductor substrate 11 may be substantially the same as the n-type semiconductor region 12.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate of a first conductivity type;
a semiconductor region of the first conductivity type formed on a top surface of the semiconductor substrate;
a lower electrode formed on a bottom surface of the semiconductor substrate;
an upper electrode formed on a top surface of the semiconductor region;
a buried semiconductor layer of a second conductivity type formed in the semiconductor region;
a first semiconductor layer of the second conductivity type, formed on the top surface of the semiconductor region and connected to the upper electrode; and
a second semiconductor layer of the second conductivity type, formed on a side surface of the semiconductor region and connected to the buried semiconductor layer and the first semiconductor layer, the second semiconductor layer having a lower second conductivity type impurity concentration than the buried semiconductor layer.

2. The semiconductor device according to claim 1, wherein the semiconductor region includes a lower portion, an upper portion, and an intermediate portion located between the lower portion and the upper portion and partitioned into parts by the buried semiconductor layer.

3. The semiconductor device according to claim 1, wherein the second semiconductor layer is completely depleted in a reverse bias state.

4. A semiconductor device comprising:
a semiconductor substrate of a first conductivity type;
a semiconductor region of the first conductivity type formed on a top surface of the semiconductor substrate and having a hole;
a lower electrode formed on a bottom surface of the semiconductor substrate;
an upper electrode formed on a top surface of the semiconductor region;
a buried semiconductor layer of a second conductivity type formed in the semiconductor region; and
a second conductivity type semiconductor layer formed on a side surface of the hole of the semiconductor region, the second conductivity type semiconductor layer being connected to the buried semiconductor layer and the upper electrode, and the second conductivity type semiconductor layer having a lower second conductivity type impurity concentration than the buried semiconductor layer.

5. The semiconductor device according to claim 4, wherein the semiconductor region includes a lower portion, an upper portion, and an intermediate portion located between the lower portion and the upper portion and partitioned into parts by the buried semiconductor layer.

6. The semiconductor device according to claim 4, wherein the second conductivity type semiconductor layer is completely depleted in a reverse bias state.

7. A semiconductor device comprising:
a semiconductor substrate of a first conductivity type;
a semiconductor region of the first conductivity type formed on a top surface of the semiconductor substrate;
a lower electrode formed on a bottom surface of the semiconductor substrate;
an upper electrode formed on a top surface of the semiconductor region;
a buried semiconductor layer of a second conductivity type formed in the semiconductor region;
a first semiconductor layer of the second conductivity type, formed on the top surface of the semiconductor region and connected to the upper electrode; and
a stacked structure formed on a side surface of the semiconductor region and comprising a first conductivity type semiconductor layer and a second semiconductor layer of the second conductivity type, the second semiconductor layer being connected to the buried semiconductor layer and the first semiconductor layer.

8. The semiconductor device according to claim 7, wherein the first conductivity type semiconductor layer is formed between the semiconductor region and the second semiconductor layer.

9. The semiconductor device according to claim 7, wherein the second semiconductor layer is formed between the semiconductor region and the first conductivity type semiconductor layer.

10. The semiconductor device according to claim 7, wherein the first conductivity type semiconductor layer has a higher first conductivity type impurity concentration than the semiconductor region.

11. The semiconductor device according to claim 7, wherein the semiconductor region includes a lower portion, an upper portion, and an intermediate portion located between the lower portion and the upper portion and partitioned into parts by the buried semiconductor layer.

12. The semiconductor device according to claim 7, wherein the second semiconductor layer is completely depleted in a reverse bias state.

13. A semiconductor device comprising:
a semiconductor substrate of a first conductivity type;
a semiconductor region of the first conductivity type formed on a top surface of the semiconductor substrate and having a hole;
a lower electrode formed on a bottom surface of the semiconductor substrate;
an upper electrode formed on a top surface of the semiconductor region;
a buried semiconductor layer of a second conductivity type formed in the semiconductor region; and
a stacked structure formed on a side surface of the hole of the semiconductor region, the stacked structure comprising a first conductivity type semiconductor layer and a second conductivity type semiconductor layer connected to the buried semiconductor layer and the upper electrode.

14. The semiconductor device according to claim 13, wherein the first conductivity type semiconductor layer is formed between the semiconductor region and the second conductivity type semiconductor layer.

15. The semiconductor device according to claim 13, wherein the second conductivity type semiconductor layer is formed between the semiconductor region and the first conductivity type semiconductor layer.

16. The semiconductor device according to claim 13, wherein the first conductivity type semiconductor layer has a higher first conductivity type impurity concentration than the semiconductor region.

17. The semiconductor device according to claim 13, wherein the semiconductor region includes a lower portion, an upper portion, and an intermediate portion located between the lower portion and the upper portion and partitioned into parts by the buried semiconductor layer.

18. The semiconductor device according to claim 13, wherein the second conductivity type semiconductor layer is completely depleted in a reverse bias state.
